(19) United States
(12) Patent Application Publication
(10) Pub. No.: US 2025/0226224 A1
(43) Pub. Date: Jul. 10, 2025

(54) ASHABLE MASK FOR SiC TRENCH IMPLANT

(71) Applicant: Applied Materials, Inc., Santa Clara, CA (US)

(72) Inventors: Ludovico MEGALINI, Mountain View, CA (US); Hans-Joachim L. GOSSMANN, Gloucester, MA (US); Qintao ZHANG, Mt Kisco, NY (US); Aswin Prathap PITCHIYA, Beverly, MA (US)

(73) Assignee: Applied Materials, Inc., Santa Clara, CA (US)

(21) Appl. No.: 18/405,873

(22) Filed: Jan. 5, 2024

(51) Int. Cl. H01L 21/04

(52) U.S. Cl. CPC H01L 21/0465

(57) ABSTRACT

Disclosed herein are methods for forming MOSFET trenches using an ashable mask. In some embodiments, a method may include providing a device structure including an epitaxial layer and a hard mask over the epitaxial layer, and forming a set of trenches through the epitaxial layer, wherein each trench of the set of trenches is defined by a sidewall and a bottom surface. The method may further include forming an ashable mask over the device structure, including within each trench of the set of trenches, and forming an implanted region in the epitaxial layer, below the bottom surface of each trench, by delivering ions into the set of trenches while the ashable mask is along the sidewall and the bottom surface of each trench of the set of trenches.

### FIELD OF THE DISCLOSURE

The present embodiments relate to semiconductor device patterning and, more particularly, to forming transistors using an ashable mask for controlled implantation of silicon carbide (SiC) device trenches.

### BACKGROUND OF THE DISCLOSURE

Medium and high-voltage SiC power metal-oxide-semiconductor field-effect transistors (MOSFETs) are often used in load switching applications where reduction of the on-resistance (Rds) of the device is desirable. SiC manufacturers have largely transitioned from a planar architecture to a trench architecture due to the performance improvement provided by the trench design.

However, trench design requires protection of the gate oxide (GOX) formed along the SiC trench sidewall and, in particular, at the trench bottom due to the increased electric field in the off-state operation. If this is not properly done, significant reliability issues occur. In some approaches, a thick bottom oxide and/or trench bottom rounding are used in an attempt to mitigate device degradation. However, these approaches are not adequate to shield the GOX from the high-electric field in the off-state, and a deep implantation is therefore necessary. High-energy implantation tools are expensive and have low-throughput, and tend to cause severe damage to the SiC crystal lattice. Furthermore, with high-energy implantation tools it is hard to accurately control overlap of implanted regions and trenches, causing current flow between trenches to be restricted, which decreases device performance.

Accordingly, improved trench formation approaches are needed to maximize scalability.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a device structure including an epitaxial layer and a hard mask over the epitaxial layer, and forming a set of trenches through the epitaxial layer, wherein each trench of the set of trenches is defined by a sidewall and a bottom surface. The method may further include forming an ashable mask over the device structure, including within each trench of the set of trenches, and forming an implanted region in the epitaxial layer, below the bottom surface of each trench, by delivering ions into the set of trenches while the ashable mask is along the sidewall and the bottom surface of each trench of the set of trenches.

In another aspect, a method of forming a transistor may include providing a device structure including an epitaxial layer and a hard mask over the epitaxial layer, and forming a set of trenches through the epitaxial layer, wherein each trench of the set of trenches is defined by a sidewall and a bottom surface extending from the sidewall. The method may further include forming an ashable mask over the device structure including along the sidewall and the bottom surface of each trench of the set of trenches, and forming an implanted region in the epitaxial layer, below the bottom surface of each trench, by delivering ions into the set of trenches and through the ashable mask.

In yet another aspect, a method of forming a transistor may include providing a device structure including an epitaxial layer and a hard mask over the epitaxial layer, and forming a set of trenches through the epitaxial layer, wherein each trench of the set of trenches is defined by a sidewall and a bottom surface extending from the sidewall. The method may further include forming an ashable mask over the device structure including along the sidewall and the bottom surface of each trench of the set of trenches, and forming an implanted region in the epitaxial layer, below the bottom surface of each trench, by delivering ions into the set of trenches and through the ashable mask.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a SiC device including a set of trenches formed therein, according to embodiments of the present disclosure;

FIG. 2 illustrates a side cross-sectional view of the SiC device including an ashable mask formed within the set of trenches, according to embodiments of the present disclosure;

FIG. 3 illustrates a side cross-sectional view of the SiC device during an ion implant to form a set of implanted regions, according to embodiments of the present disclosure; and

FIG. 4 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein advantageously enable a more controlled trench implant for a SiC trench device (e.g., MOSFET). As will be described herein in greater detail, trenches of the device may be lined with an ashable carbon-based hard mask, which protects the trench sidewalls during implant, and which controls a profile of an implanted region beneath the trenches. By restricting overexpansion of the implant region, current flowing between the trenches can be maximized without additional and/or difficult lithography steps. In some embodiments, the carbon-based hardmask can be deposited uniformly along the SiC trench sidewall. Furthermore, in some embodiments, the carbon-based hardmask thickness ratio of sidewall-to-bottom can be tuned, as desired.

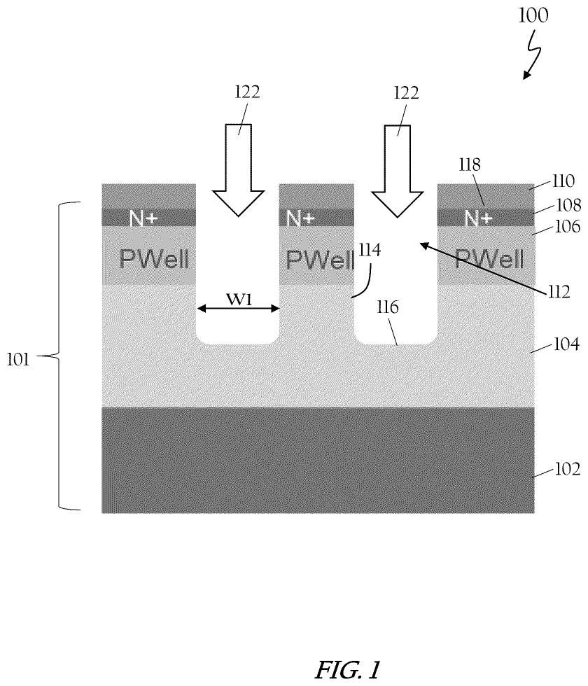

FIG. 1 is a side cross-sectional view of an example device 100, such as a MOSFET, according to one or more embodiments described herein. The device 100 may include a device structure 101 having a substrate 102, an epitaxial layer 104, a well 106, and a source region or layer 108. Although non-limiting, the epitaxial layer 104 may be a silicon carbide (SiC) n-type drift layer, the well 106 may be a p-type well, and the source layer 108 may be an n+source layer. In other embodiments, the source layer 108 may include n+ and p+ regions next to each other, wherein p+serves as a PWell contact and n+serves as the source layer. As further shown, a hardmask 110 may be provided over the device structure 101, e.g., directly atop the source layer 108.

As further shown, one or more trenches 112 may be formed in the device 100, e.g., using one or more blocking and vertical etch processes 122 to form a sidewall 114 with a slope of approximately 80 to 90 degrees relative to a plane defined by a top surface 118 of the device structure 101. The trenches 112 may further include a bottom surface 116 extending from the sidewall 114. In some embodiments, the trenches 112 may be formed after the well 106, the source layer 108, and the hardmask 110 are formed.

Although not shown, one or more isolation shields may be provided between adjacent trenches, e.g., in the case the device 100 is a dual trench gate transistor. Furthermore, although shown as a single layer, the epitaxial layer 104 may include multiple layers in other embodiments. As known, the well 106 may be formed using a plurality of doping steps or epitaxy steps. It will be appreciated that layers and elements of device 100 are non-limiting and provided for the purposes of demonstrating certain aspects of the disclosure. Other SiC MOSFET structures are possible in alternative embodiments.

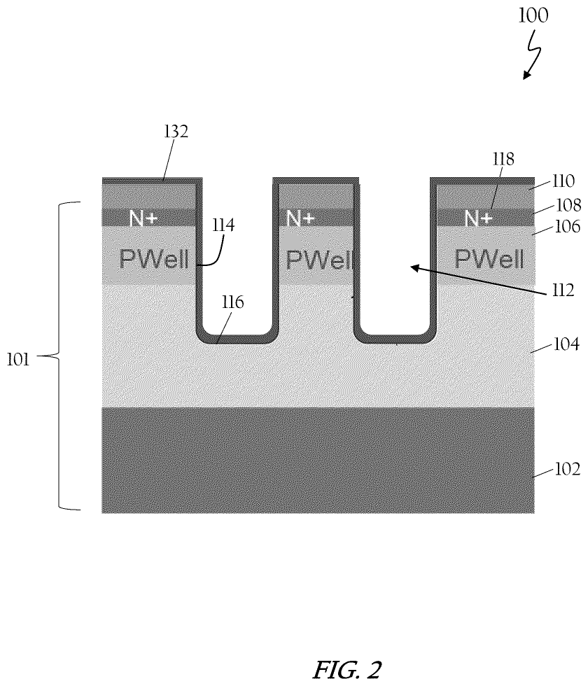

FIG. 2 demonstrates the device 100 following formation of an ashable mask 132. In some embodiments, the ashable mask 132 may be an ashable carbon-based hard mask conformally deposited atop the hardmask 110 and within each of the trenches 112. As shown, the ashable mask 132 may be formed along the sidewall 114 and the bottom surface 116 of each trench 112. In some embodiments, the ashable mask 132 may have a constant thickness along both the sidewall 114 and the bottom surface 116. In other embodiments, the ashable mask 132 may have a varied thickness ratio between the sidewall 114 and the bottom surface 116, as desired.

In various embodiments, the ashable mask 132 may be made from one or more ashable materials, such as carbon (in its various solid forms, graphite, diamond, diamond-like, amorphous, among others) and other organic materials such as hydrocarbon-containing polymers. Although non-limiting, the ashable mask 132 may be an amorphous carbon layer, which is removable by means of a plasma or other dry process (“ashing”). More specifically, ashing processes may include dry stripping including plasma etching (typically utilizing an oxidizing plasma such as O₂, ammonia, water, H₂O₂, among other plasmas). However, non-plasma dry stripping processes may also be used, such as etching with oxidizing gases.

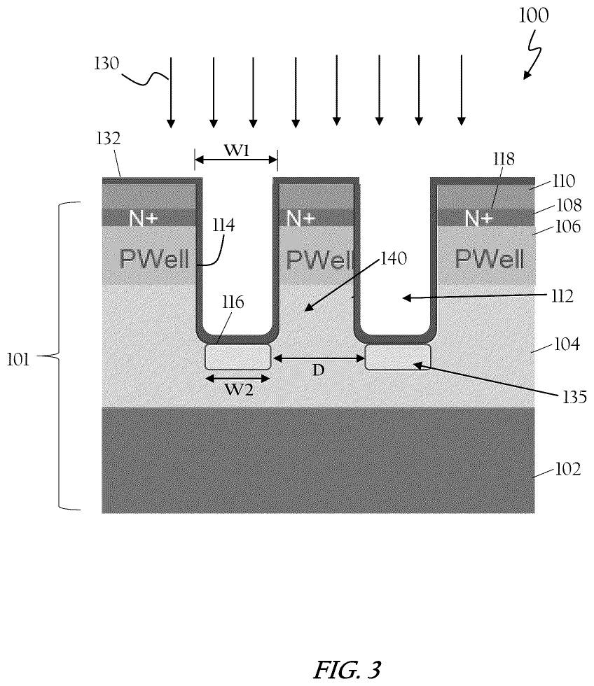

As shown in FIG. 3, an ion implant 130 may be performed to the device 100 to form an implanted region 135 in the epitaxial layer 104, below the bottom surface 116 of each trench 112. In some embodiments, the implanted regions 135 may be p-type or n-type regions, and the ion implant 130 may be a vertical implant, which delivers the ions into the trenches 112 while the ashable mask 132 is along the sidewall 114 and the bottom surface 116. Although non-limiting, the ion implant 130 may include one or more beamline implants delivered at a pre-defined angle, a predefined energy, a predefined dose, etc. For example, one or more implantation ion species, such as Al, B, P, N, may be delivered at an energy between 10 KeV and 3 MeV and at a dose between 1E13 and 1E15/cm2.

Due to the presence of the ashable mask 132 and the angle of the ion implant 130, the ions of the ion implant 130 do not significantly impact the sidewall 114 of each trench 112. Furthermore, the ashable mask 132 along the bottom surface 116 of the trenches 112 controls the profile and lateral expansion of the implanted regions 135. For example, increasing a thickness of the ashable mask 132 along the bottom surface 116 decreases lateral expansion of the implanted regions 135, thus maximizing a distance (‘D’) therebetween. Said another way, in some embodiments, a first width (‘W1’) corresponding to a width of the trenches 112 may be greater than a second width (‘W2’) corresponding to a width of the implanted regions 135. Beneficially, current flowing through a channel area 140 between the trenches 112 is maximized, thus allowing adequate performance of the device 100. To increase the width of the implanted regions 135, the thickness of the ashable mask 132 along the bottom surface 116 may be decreased.

Although not shown, processing of the device 100 may continue as is known in the art. For example, a removal process may then be performed to remove the ashable mask 132 from the trenches 112. As mentioned above, in some embodiments, the ashable mask 132 may be removed by one or more plasma or ashing processes.

Next, a P+contact implant may be performed, followed by an annealing process and a polysilicon gate material deposition within the trench 112. More specifically, the hardmask 110 may be removed, and a gate oxide layer is formed over the device structure 101, including within the trenches 112. In some embodiments, the gate oxide layer is formed by a thermal oxidation process to device 100 to form a uniform-thickness oxide along the sidewall 114 and the bottom surface 116. The gate material may then be formed within the trenches 112.

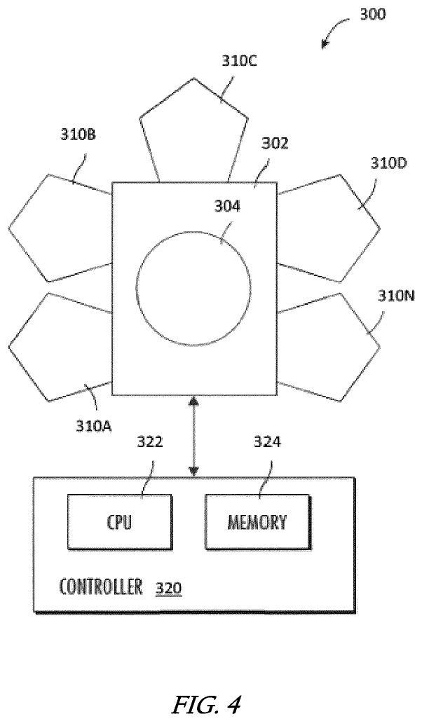

FIG. 4 illustrates a schematic diagram of a system/processing apparatus 300 useful to perform processes described herein. In some embodiments, the system 300 may be a cluster tool operable to perform processes necessary to form the device 100 described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber operable to deposit one or more layers of the device, such the ashable mask 132, the substrate 102, the epitaxial layer 104, the well 106, the source layer 108, and the hardmask 110. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition.

In some embodiments, processing chamber 310B may be an etch chamber operable to form trenches 112 through the body of the device 100. In some embodiments, processing chamber 310B may be used for wet and/or dry etch processes. In some embodiments, the processing chamber 310B may be operable to planarize the device 100, e.g., to partially remove the fill material.

In some embodiments, processing chamber 310C may be operable to perform one or more implantation processes, such as the ion implant 130 to form the implanted regions 135. For example, the processing chamber 310C may house a beam-line ion implantation processing apparatus, such as the Varian VIISTAR Trident, available from Applied Materials Inc., Santa Clara, CA. The ion implantation processing apparatus may include an ion source for generating ions, and a plurality of additional beam-line components for directing the ions from the ion source to the device 100.

In some embodiments, processing chamber 310D may be operable to perform one or more annealing processes.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processor 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a device structure including an epitaxial layer and a hard mask over the epitaxial layer;
forming a set of trenches through the epitaxial layer, wherein each trench of the set of trenches is defined by a sidewall and a bottom surface;
forming an ashable mask over the device structure including within each trench of the set of trenches; and
forming an implanted region in the epitaxial layer, below the bottom surface of each trench, by delivering ions into the set of trenches while the ashable mask is along the sidewall and the bottom surface of each trench of the set of trenches.

2. The method of claim 1, wherein forming the ashable mask comprises depositing a carbon ashable hard mask along the sidewall and the bottom surface.

3. The method of claim 2, wherein a first thickness of the carbon ashable hard mask along the sidewall is different than a second thickness of the carbon ashable hard mask along the bottom surface.

4. The method of claim 1, wherein each trench of the set of trenches has a first width, wherein the implanted region has a second width, and wherein the second width is less than the first width.

5. The method of claim 1, wherein delivering ions into the set of trenches comprises performing a vertical ion implant.

6. The method of claim 1, wherein providing the device structure further comprises forming a source region over a well, wherein the trench is formed through the epitaxial layer, the well, and the source region.

7. The method of claim 1, wherein the implanted region is an n-type implanted region or a p-type implanted region.

8. A method of forming a transistor, comprising:
providing a device structure including an epitaxial layer and a hard mask over the epitaxial layer;
forming a set of trenches through the epitaxial layer, wherein each trench of the set of trenches is defined by a sidewall and a bottom surface extending from the sidewall;
forming an ashable mask over the device structure including along the sidewall and the bottom surface of each trench of the set of trenches; and
forming an implanted region in the epitaxial layer, below the bottom surface of each trench, by delivering ions into the set of trenches and through the ashable mask.

9. The method of claim 8, wherein forming the ashable mask comprises depositing a carbon ashable hard mask along the sidewall and the bottom surface.

10. The method of claim 9, wherein a first thickness of the carbon ashable hard mask along the sidewall is different than a second thickness of the carbon ashable hard mask along the bottom surface.

11. The method of claim 8, wherein each trench of the set of trenches has a first width, wherein the implanted region has a second width, and wherein the second width is less than the first width.

12. The method of claim 8, wherein delivering ions into the set of trenches comprises performing a vertical ion implant.

13. The method of claim 8, wherein providing the device structure further comprises forming a source region over a well, wherein the trench is formed through the epitaxial layer, the well, and the source region.

14. The method of claim 8, wherein the implanted region is an n-type implanted region or a p-type implanted region.

15. A method of forming a silicon carbide metal-oxide-semiconductor field-effect transistor, the method comprising:
providing a device structure including an epitaxial layer and a hard mask over the epitaxial layer;
forming a set of trenches through the epitaxial layer, wherein each trench of the set of trenches is defined by a sidewall and a bottom surface extending from the sidewall;
forming an ashable mask over the device structure including along the sidewall and the bottom surface of each trench of the set of trenches; and
forming an implanted region in the epitaxial layer, below the bottom surface of each trench, by delivering ions through the ashable mask along the bottom surface of each trench of the set of trenches.

16. The method of claim 15, wherein forming the ashable mask comprises depositing a carbon ashable hard mask along the sidewall and the bottom surface.

17. The method of claim 16, wherein a first thickness of the carbon ashable hard mask along the sidewall is different than a second thickness of the carbon ashable hard mask along the bottom surface.

18. The method of claim 15, wherein each trench of the set of trenches has a first width, wherein the implanted region has a second width, and wherein the second width is less than the first width.

19. The method of claim 15, wherein delivering ions into the set of trenches comprises performing a vertical ion implant.

20. The method of claim 15, wherein providing the device structure further comprises forming a source region over a well, wherein the trench is formed through the epitaxial layer, the well, and the source region.
